(19) United States
(12) Patent Application Publication
(10) Pub. No.: US 2025/0174585 A1
(43) Pub. Date: May 29, 2025

(54) SEMICONDUCTOR DIE AND SEMICONDUCTOR PACKAGE INCLUDING THE SAME

(71) Applicant: SAMSUNG ELECTRONICS CO., LTD., Gyeonggi-do (KR)

(72) Inventors: Hyeonjae KIM, Suwon-si (KR); Yongjae KIM, Suwon-si (KR); Sungwoo PARK, Suwon-si (KR); Junseop BYEON, Suwon-si (KR); Semin OH, Suwon-si (KR)

(73) Assignee: SAMSUNG ELECTRONICS CO., LTD., Gyeonggi-do (KR)

(21) Appl. No.: 18/901,979

(22) Filed: Sep. 30, 2024

(30) Foreign Application Priority Data
Nov. 29, 2023 (KR) 10-2023-0169369

(51) Int. Cl. H01L 23/00; H01L 23/29; H01L 23/31; H01L 25/065

(52) U.S. Cl. CPC H01L 24/06; H01L 23/3171; H01L 23/3192; H01L 24/05; H01L 24/13; H01L 25/0657; H01L 23/291; H01L 24/03; H01L 24/16; H01L 2224/0391; H01L 2224/0401; H01L 2224/05073; H01L 2224/05076; H01L 2224/05083; H01L 2224/05087; H01L 2224/06051; H01L 2224/13082; H01L 2224/16146; H01L 2225/06513; H01L 2225/06541

(57) ABSTRACT

Provided is a semiconductor die including a substrate including a first surface and a second surface, interconnection lines on the first surface of the substrate, an interlayer insulating layer on the first surface of the substrate and the interconnection lines, a back passivation layer on the second surface of the substrate, through-vias penetrating the substrate, first conductive pads being in contact with some of the through-vias and on the second surface of the substrate, and second conductive pads being in contact with others of the through-vias and on the back passivation layer, each of the first conductive pads includes a first pad portion buried in the back passivation layer, a second pad portion protruding above the back passivation layer, a first barrier pattern on a bottom surface and side surfaces of the first pad portion, and a second barrier pattern between the first pad portion and the second pad portion.

### CROSS-REFERENCE TO RELATED APPLICATION

This application claims priority to Korean Patent Application No. 10-2023-0169369, filed on Nov. 29, 2023, in the Korean Intellectual Property Office, the disclosure of which is incorporated herein in its entirety by reference.

### BACKGROUND

Embodiments of the present disclosure relate to a semiconductor die and a semiconductor package including the same, and more particularly, to a semiconductor die including pads partially buried in a passivation layer and a semiconductor package including the same.

Relatively small, multi-functional and large-capacity electronic devices have been demanded with the development of an electronic industry and user's demands, and thus a semiconductor package including a plurality of semiconductor chips has been required. As the semiconductor chips included in the semiconductor package have been highly integrated, a semiconductor package for connecting adjacent semiconductor chips by using a semiconductor die has been studied to increase the number and a density of connection bumps adhered to connection pads of the semiconductor chip.

### SUMMARY

One or more embodiments provide a semiconductor die with improved durability.

One or more embodiments also provide a semiconductor package with improved durability and reliability.

According to an aspect of one or more embodiments, there is provided a semiconductor die including a substrate including a first surface and a second surface which are opposite to each other, interconnection lines on the first surface of the substrate, an interlayer insulating layer on the first surface of the substrate and on the interconnection lines, a back passivation layer on the second surface of the substrate, through-vias penetrating the substrate, a plurality of first conductive pads being in contact with some of the through-vias and on the second surface of the substrate, and a plurality of second conductive pads being in contact with others of the through-vias and on the back passivation layer, wherein each first conductive pad of the first conductive pads includes a first pad portion buried in the back passivation layer, a second pad portion protruding above the back passivation layer, a first barrier pattern on a bottom surface and side surfaces of the first pad portion, and a second barrier pattern between the first pad portion and the second pad portion.

According to another aspect of one or more embodiments, there is provided a semiconductor die including a substrate including a first surface and a second surface which are opposite to each other, interconnection lines on the first surface of the substrate, an interlayer insulating layer on the first surface of the substrate and the interconnection lines, a first passivation layer on the second surface of the substrate, a second passivation layer on a portion of the first passivation layer, a material of the second passivation layer being different from a material of the first passivation layer, through-vias penetrating the substrate, a plurality of first conductive pads being in contact with some of the through-vias and on the second surface of the substrate, a plurality of second conductive pads being in contact with others of the through-vias and on the second passivation layer, bump structures connected to the first conductive pads and the second conductive pads, respectively, and a pad insulating layer on the first conductive pads, the second conductive pads, and the second passivation layer, wherein each first conductive pad of the first conductive pads includes a first pad portion penetrating the second passivation layer and buried in the first passivation layer, a second pad portion on the second passivation layer, a first barrier pattern on a bottom surface and side surfaces of the first pad portion, and a second barrier pattern between the first pad portion and the second pad portion, wherein each of the second conductive pads includes a third pad portion, and a third barrier pattern on a bottom surface of the third pad portion, wherein each first conductive pad of the first conductive pads has a first thickness, and wherein each second conductive pad of the second conductive pads has a second thickness less than the first thickness.

According to still another aspect of one or more embodiments, there is provided a semiconductor package including a package substrate, a semiconductor die on the package substrate, and a first semiconductor chip and a plurality of second semiconductor chips, which are side by side in a first direction on the semiconductor die, wherein the semiconductor die includes a die substrate, a back passivation layer on a bottom surface of the die substrate, through-vias penetrating the die substrate, a plurality of first conductive pads being in contact with some of the through-vias and on the bottom surface of the die substrate, a plurality of second conductive pads being in contact with others of the through-vias and on the back passivation layer, and a pad insulating layer on the first conductive pads, the second conductive pads and the back passivation layer, wherein the back passivation layer includes a first passivation layer, and a second passivation layer on the first passivation layer, a material of the second passivation layer being different from a material of the first passivation layer, wherein each first conductive pad of the first conductive pads includes a first pad portion penetrating the second passivation layer and buried in at least a portion of the first passivation layer, a second pad portion protruding from the second passivation layer, a first barrier pattern on a bottom surface and side surfaces of the first pad portion, and a second barrier pattern between the first pad portion and the second pad portion, wherein each of the second conductive pads includes a third pad portion on a top surface of the second passivation layer, and a third barrier pattern between the third pad portion and the second passivation layer.

### BRIEF DESCRIPTION OF DRAWINGS

The above and other aspects, features, and advantages of the embodiments will be more clearly understood from the following detailed description, taken in conjunction with the accompanying drawings, in which:

FIG. 1A is a plan view illustrating a semiconductor die according to one or more embodiments;

FIG. 1B is a cross-sectional view taken along a line A-A′ of FIG. 1A according to one or more embodiments;

FIG. 1C is an enlarged view of a portion ‘P1’ of FIG. 1B according to one or more embodiments;

FIG. 2 is an enlarged view of the portion ‘P1’ of FIG. 1B according to one or more embodiments;

FIGS. 3A to 3L are partial enlarged cross-sectional views illustrating a method of manufacturing the semiconductor die of FIGS. 1B and 1C according to one or more embodiments;

FIG. 4 is a cross-sectional view illustrating a semiconductor package according to one or more embodiments; and

FIG. 5 is a cross-sectional view illustrating a semiconductor package according to one or more embodiments.

### DETAILED DESCRIPTION

Hereinafter, various embodiments will be described in detail with reference to the attached drawings. Embodiments described herein are example embodiments, and thus, the disclosure is not limited thereto.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

Herein, a direction parallel to a main surface of the semiconductor die 1000 may be referred to as a horizontal direction (X direction and/or Y direction), and a direction perpendicular to the horizontal direction (X direction and/or Y direction) may be referred to as a vertical direction (Z direction).

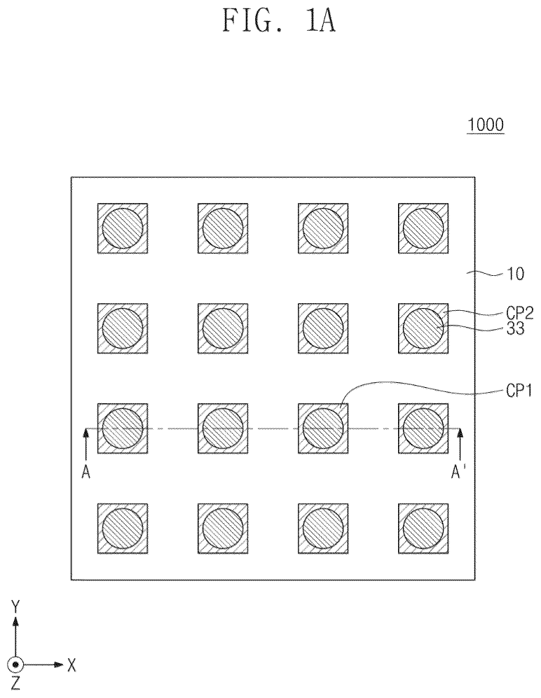

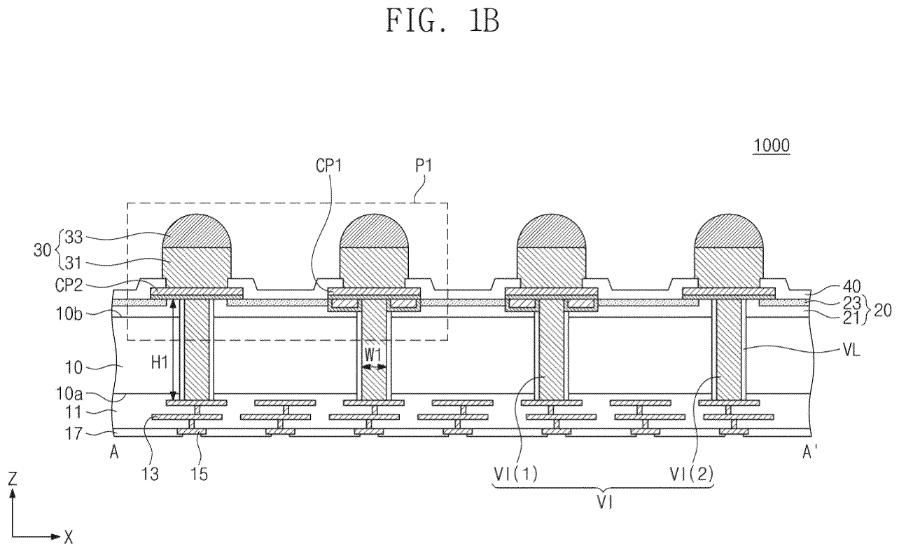

FIG. 1A is a plan view illustrating a semiconductor die according to one or more embodiments. FIG. 1B is a cross-sectional view taken along a line A-A′ of FIG. 1A according to one or more embodiments. FIG. 1C is an enlarged view of a portion ‘P1’ of FIG. 1B according to one or more embodiments.

Referring to FIGS. 1A and 1B, a semiconductor die 1000 according to the one or more embodiments may include a substrate 10, interconnection lines 13, an interlayer insulating layer 11, first connection pads 15, a front passivation layer 17, a back passivation layer 20, through-vias VI, first and second conductive pads CP1 and CP2, a pad insulating layer 40, and bump structures 30. In the present disclosure, the semiconductor die 1000 may also be referred to as an interposer or an interposer die. In the present disclosure, the substrate 10 may also be referred to as a die substrate or an interposer substrate.

The substrate 10 may include a first surface 10a and a second surface 10b, which are opposite to each other. The first surface 10a may be referred to as a front surface 10a. The second surface 10b may be referred to as a back surface 10b. The substrate 10 may include a semiconductor material, glass, and/or an organic material. For example, the substrate 10 may include silicon.

The interconnection lines 13 may be disposed on the first surface 10a of the substrate 10. The interconnection lines 13 may correspond to multi-layered interconnection patterns. The interconnection lines 13 may be used to transmit signals between a printed circuit board connected to a bottom surface of the semiconductor die 1000 and a plurality of semiconductor chips disposed on a top surface of the semiconductor die 1000. In some embodiments, the interconnection lines 13 may be redistribution patterns of a redistribution layer (RDL). For example, the interconnection lines 13 may include a metal such as, for example, copper, aluminum, gold, nickel, or titanium.

In addition, transistors, capacitors and/or memory cells may be disposed on the first surface 10a of the substrate 10. The transistors, the capacitors and/or the memory cells may be connected to the interconnection lines 13 and may constitute at least one of various integrated circuits.

The interlayer insulating layer 11 may cover the interconnection lines 13 and may be disposed on the first surface 10a of the substrate 10. The interlayer insulating layer 11 may have a single-layered or multi-layered structure including, for example, at least one of silicon oxide, silicon nitride, silicon oxynitride, or a porous insulating material. According to embodiments, the interlayer insulating layer 11 may be formed of a photoimageable dielectric (PID).

The first connection pads 15 may be disposed on the interlayer insulating layer 11. Each of the first connection pads 15 may be connected to a corresponding one of the interconnection lines 13. The first connection pads 15 may include a metal such as, for example, copper, gold, nickel, aluminum, tungsten, or titanium.

The front passivation layer 17 may cover portions of the first connection pads 15 and may be disposed on the interlayer insulating layer 11. The front passivation layer 17 may have a single-layered or multi-layered structure including at least one of silicon oxide, silicon nitride, or silicon carbonitride. In certain embodiments, the front passivation layer 17 may be formed of a PID.

The back passivation layer 20 may include a first passivation layer 21 and a second passivation layer 23. The first passivation layer 21 may cover the second surface 10b of the substrate 10. The first passivation layer 21 may cover portions of side surfaces of the through-vias VI. A through-insulating layer VL may be disposed between the first passivation layer 21 and each of the through-vias VI. The second passivation layer 23 may cover a portion of the first passivation layer 21. The second passivation layer 23 may not cover the through-vias VI.

The back passivation layer 20 may have a single-layered or multi-layered structure including, for example, at least one of silicon oxide, silicon nitride, or silicon carbonitride. The first passivation layer 21 and the second passivation layer 23 may be formed of different materials. For example, the first passivation layer 21 may include an oxide, and the second passivation layer 23 may include a nitride. For example, the first passivation layer 21 may include silicon oxide, and the second passivation layer 23 may include silicon nitride.

The through-vias VI may penetrate the substrate 10. Each of the through-vias VI may be in contact with a corresponding one of the first and second conductive pads CP1 and CP2. The through-vias VI may include first through-vias VI(1) and second through-vias VI(2). The first through-vias VI(1) may be disposed in a central portion of the substrate 10. The second through-vias VI(2) may be disposed in an edge portion (peripheral portion) of the substrate 10. The first through-via VI(1) may be in contact with the first conductive pad CP1. The first through-via VI(1) may extend into the first conductive pad CP1. For example, a bottommost surface of the first conductive pad CP1 may be lower than a top surface of the first through-via VI(1). The second through-via VI(2) may be in contact with the second conductive pad CP2.

Top surfaces of the through-vias VI may be located at the same level (i.e., a first level LV1) as a top surface of the second passivation layer 23. The through-insulating layer VL may be disposed between each of the through-vias VI and the substrate 10. Referring to FIG. 1B, a width W1 of each of the through-vias VI may range from 1 μm to 30 μm in the horizontal direction, and a height H1 of each of the through-vias VI may range from 1 μm to 120 μm in the vertical direction. The through-vias VI may include a metal such as, for example, copper, aluminum, or tungsten. The through-insulating layer VL may have a single-layered or multi-layered structure including, for example, at least one of silicon oxide, silicon nitride, or silicon oxynitride. The through-insulating layer VL may include an air gap region.

The first conductive pads CP1 may be disposed on the second surface 10b of the substrate 10. Each of the first conductive pads CP1 may include a first barrier pattern BT1, a second barrier pattern BT2(1), a first pad portion PT1, and a second pad portion PT2(1).

The first pad portion PT1 may be buried in the back passivation layer 20. For example, the first pad portion PT1 may penetrate the second passivation layer 23 and may be buried in at least a portion of the first passivation layer 21. The first pad portion PT1 may not completely penetrate the first passivation layer 21. Similar to FIG. 1C, a top surface of the first pad portion PT1 may be located at a same level as the first level LV1 of the top surface of the second passivation layer 23. The first conductive pads CP1 may be buried from the top surface of the back passivation layer 20 (or the top surface of the second passivation layer 23) by a depth D1 of 1 μm to 5 μm. For example, the first conductive pads CP1 may be buried from the first level LV1 by a depth D1 of 1 μm to 5 μm in the vertical direction. A second level LV2 of a bottom surface of each of the first conductive pads CP1 may be located between a third level LV3 of the top surface of the first passivation layer 21 and a fourth level LV4 of a bottom surface of the first passivation layer 21. The first barrier pattern BT1 may surround a bottom surface and side surfaces of the first pad portion PT1. The first barrier pattern BT1 may be disposed between the through-via VI in contact with the first conductive pad CP1 and the first pad portion PT1 of the first conductive pad CP1.

The second pad portion PT2(1) may be disposed on the second passivation layer 23. For example, the second pad portion PT2(1) may protrude above the second passivation layer 23 in the vertical direction. For example, a top surface of the second pad portion PT2(a) may be at a higher level than a top surface of the passivation layer 23 in the vertical direction. The second barrier pattern BT2(1) may be disposed between the first pad portion PT1 and the second pad portion PT2(1).

The second conductive pads CP2 may be disposed on the second passivation layer 23. Each of the second conductive pads CP2 may include a third barrier pattern BT2(2) and a third pad portion PT2(2), which are sequentially stacked. The third barrier pattern BT2(2) and the third pad portion PT2(2) may not be buried in the second passivation layer 23. For example, the third barrier pattern BT2(2) may be disposed between the third pad portion PT2(2) and the second passivation layer 23. A bottom surface of the second barrier pattern BT2(1) of each of the first conductive pads CP1 and a bottom surface of the third barrier pattern BT2(2) of each of the second conductive pads CP2 may be located at the same level (i.e., the first level LV1) as the top surface of the second passivation layer 23 in the vertical direction.

Each of widths W2 of the first and second conductive pads CP1 and CP2 in the horizontal direction may range from 1 μm to200 μm. The first and second conductive pads CP1 and CP2 may have the same width or different widths. Each of the first conductive pads CP1 may have a first thickness T1 of 1 μm to 15 μm in the vertical direction. Each of the second conductive pads CP2 may have a second thickness T2 which is less than the first thickness T1 and ranges from 1 μm to 10 μm in the vertical direction.

Each of the first and second conductive pads CP1 and CP2 has a square shape in a top plan view, but embodiments are not limited thereto, and, for example, each of the first and second conductive pads CP1 and CP2 may have one of various shapes such as a rectangular shape, a circular shape and an elliptical shape when viewed in a top plan view. Each of the first and second conductive pads CP1 and CP2 may include a metal such as, for example, copper, gold, nickel, aluminum, tungsten, or titanium. For example, each of the first to third barrier patterns BT1, BT2(1) and BT2(2) may include, for example, at least one of titanium, tantalum, titanium nitride, tantalum nitride, or tungsten nitride.

The pad insulating layer 40 may cover portions of top surfaces and side surfaces of the first and second conductive pads CP1 and CP2 and the second passivation layer 23. For example, the pad insulating layer 40 may include a photoimageable dielectric (PID) material. For example, the photoimageable dielectric (PID) material may include at least one of photosensitive polyimide, polybenzoxazole, a phenol-based polymer, or a benzocyclobutene-based polymer.

The bump structures 30 may be bonded to and contact the first and second conductive pads CP1 and CP2, respectively. Each of the bump structures 30 may include a pillar portion 31 and a solder portion 33. The pillar portion 31 may be bonded to and contact each of the first and second conductive pads CP1 and CP2. The solder portion 33 may be bonded to and contact the pillar portion 31. According to another embodiment, each of the bump structures 30 may include a solder ball. For example, the bump structures 30 may include a metal such as, for example, copper, aluminum, lead, nickel, zinc, silver, tin, and/or gold.

The thicknesses of the first and second conductive pads CP1 and CP2 in the vertical direction on the second surface 10b opposite to the first surface 10a may be increased to compensate or offset warpage of the semiconductor die 1000 caused by increases in number and density of the interconnection lines 13 on the first surface 10a of the semiconductor die 1000. When the thicknesses of the first and second conductive pads CP1 and CP2 are equal to each other, it may be difficult to separately control different degrees of the warpage in different regions of the semiconductor die 1000.

According to embodiments, the first and second conductive pads CP1 and CP2 having different thicknesses may be disposed in different regions of the semiconductor die 1000 to more effectively control degrees of the warpage of the semiconductor die 1000. For example, the thicknesses of the first conductive pads CP1 disposed in a central portion of the semiconductor die 1000 may be greater than the thicknesses of the second conductive pads CP2 disposed in an edge portion (peripheral portion) of the semiconductor die 1000, and thus the warpage of the semiconductor die 1000 may be minimized or prevented. According to one or more embodiments, the thicknesses of the first conductive pads CP1 located in a region, in which a degree of the warpage is relatively high, of the semiconductor die 1000 may be selectively increased. Thus, the semiconductor die 1000 with improved durability may be provided.

Referring to FIG. 1C, each of the first and second conductive pads CP1 and CP2 may include an edge portion EG provided at its upper portion. The pad insulating layer 40 may cover the edge portions EG of the first and second conductive pads CP1 and CP2. When the thickness of the second pad portion PT2(1), protruding above the second passivation layer 23, of the first conductive pad CP1 is increased to control the warpage of the semiconductor die 1000, the edge portion EG of the first conductive pad CP1 may be exposed to the outside of the pad insulating layer 40. However, according embodiments, the thickness of the first pad portion PT1, disposed in the back passivation layer 20, of the first conductive pad CP1 may be increased to prevent the edge portion EG of the first conductive pad CP1 from being exposed to the outside of the pad insulating layer 40. Thus, the semiconductor die 1000 with improved durability may be provided.

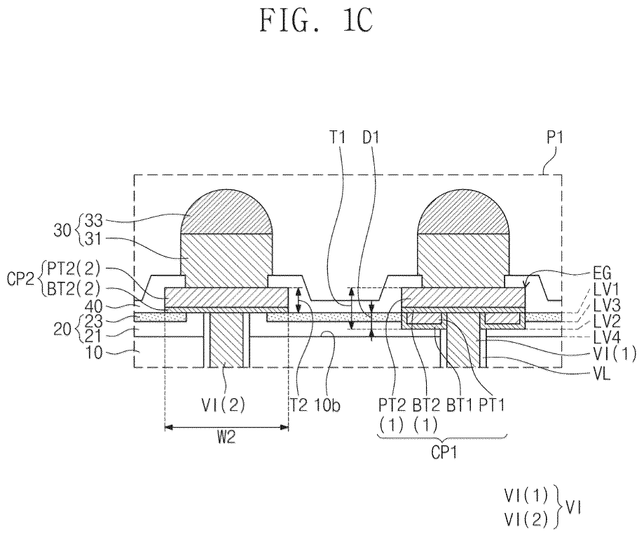

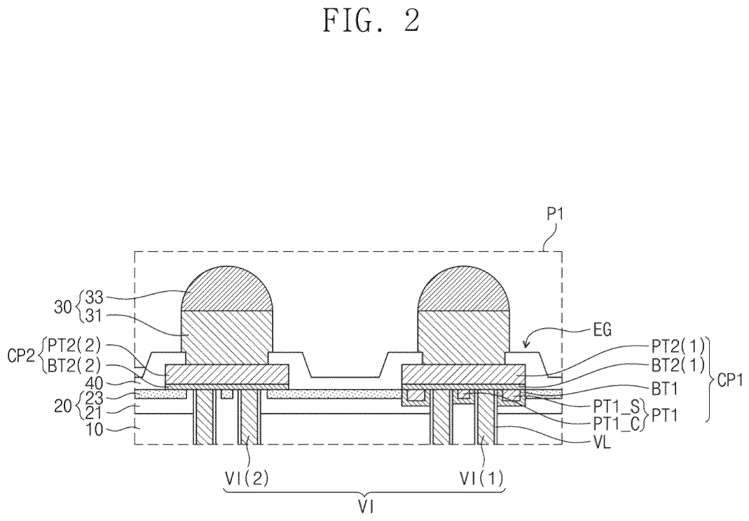

FIG. 2 is an enlarged view of the portion ‘P1’ of FIG. 1B according to one or more embodiments.

Referring to FIG. 2, according to one or more embodiments, a plurality of the through-vias VI may be connected to each of the first and second conductive pads CP1 and CP2. For example, two or more first through-vias VI(1) may be connected to each of the first conductive pads CP1, and two or more second through-vias VI(2) may be connected to each of the second conductive pads CP2. For example, a first pad portion PT1 of each of the first conductive pads CP1 may include a central portion PT1_C and an edge portion PT1_S.

The central portion PT1_C may be located between the first through-vias VI(1) connected to the first conductive pad CP1. The edge portion PT1_S may be located outside the first through-vias VI(1) connected to the first conductive pad CP1 and may surround the first through-vias VI(1) in a top plan view. The first barrier pattern BT1 of the first conductive pad CP1 may be disposed between the central portion PT1_C and the first through-vias VI(1) and between the edge portion PT1_S and the first through-vias VI(1).

A portion of the second passivation layer 23 may be located between the second through-vias VI(2) connected to the second conductive pad CP2. According to another embodiment, the second passivation layer 23 may not exist between the second through-vias VI(2) connected to the second conductive pad CP2. The second passivation layer 23 may not cover the second through-vias VI(2) connected to the second conductive pad CP2. Other components may be the same/similar as described with reference to FIGS. 1A to 1C.

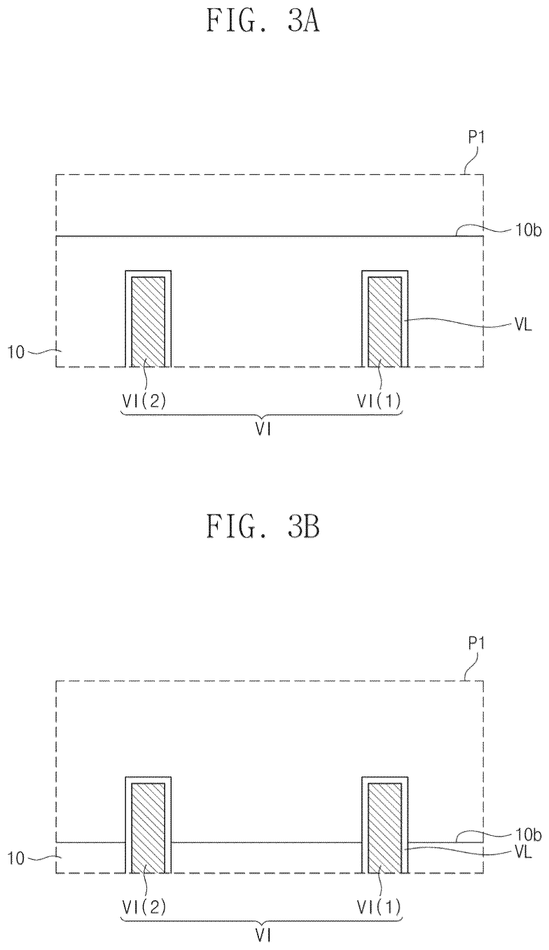

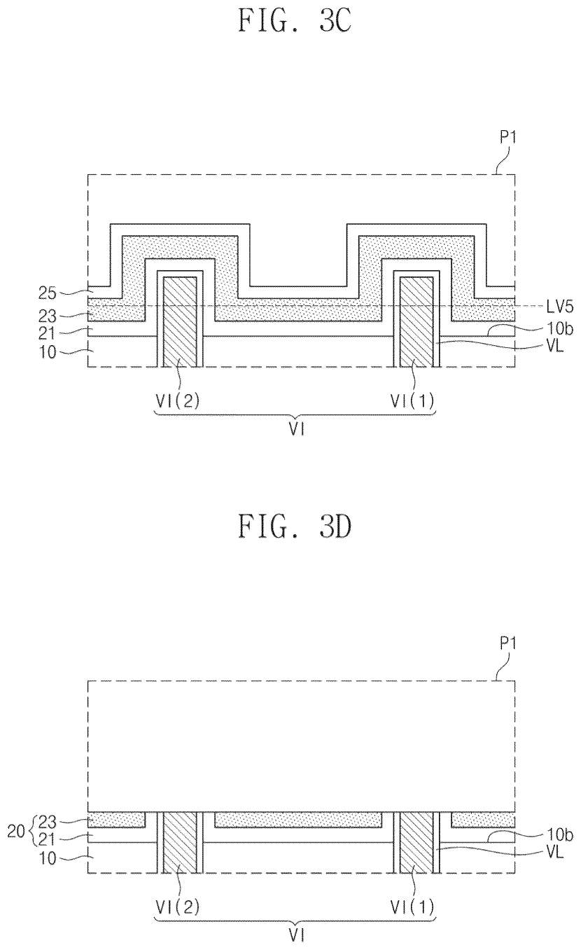

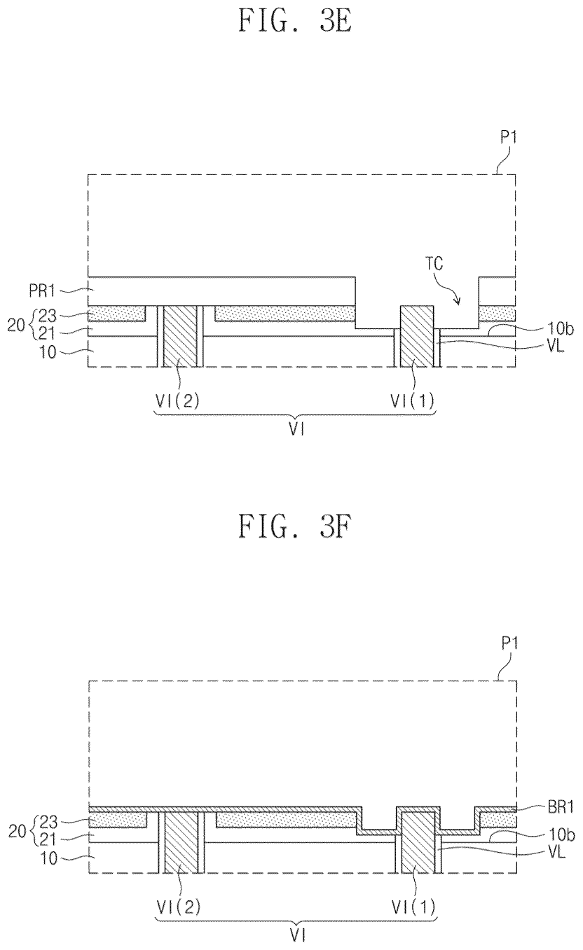

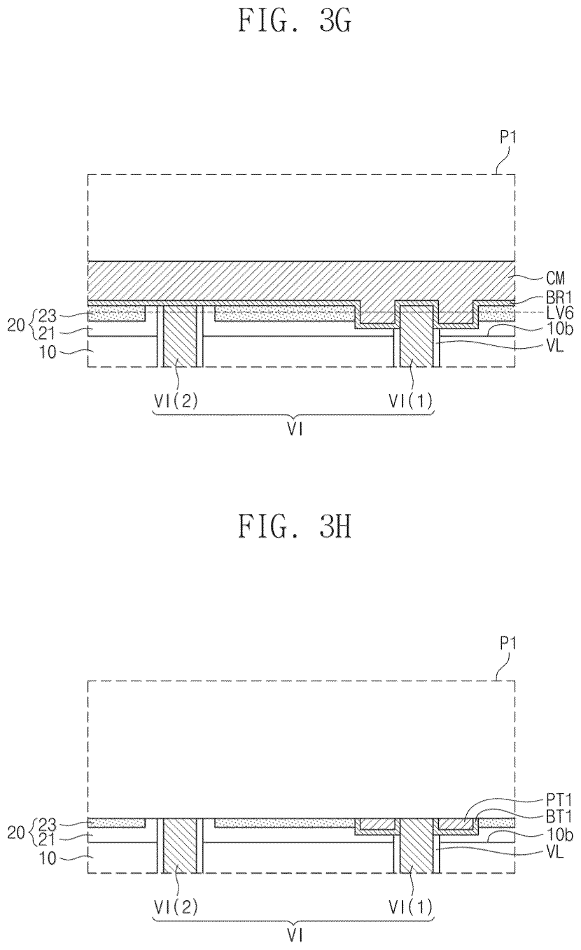

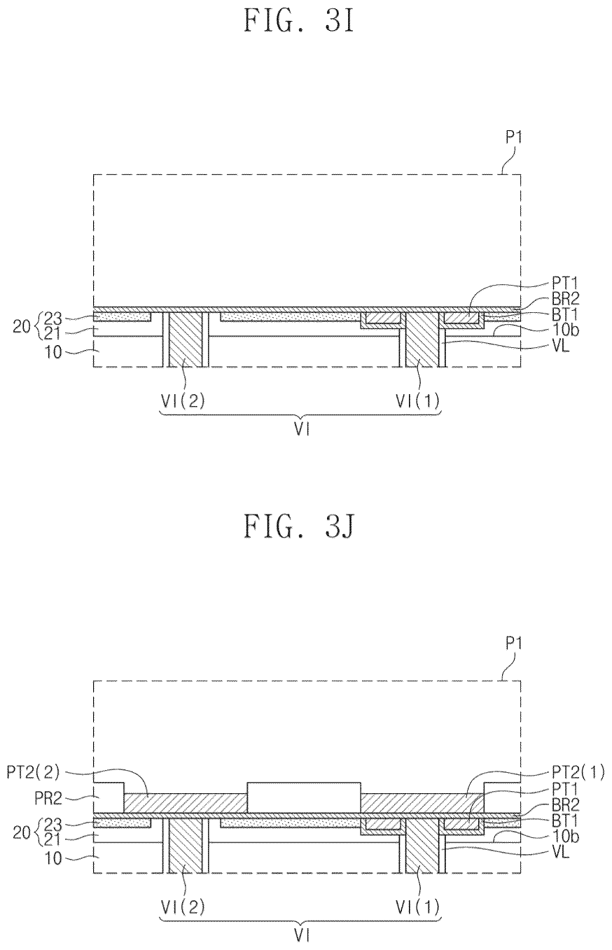

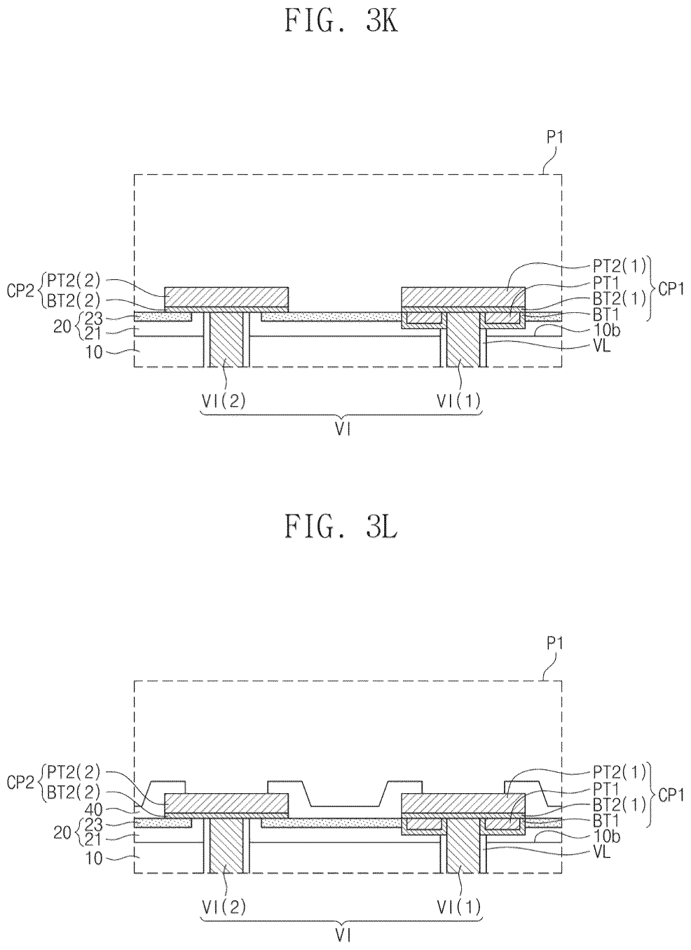

FIGS. 3A to 3L are partial enlarged cross-sectional views illustrating a method of manufacturing the semiconductor die of FIGS. 1B and 1C according to one or more embodiments.

Referring to FIGS. 1B and 3A, a substrate 10 may be provided. The substrate 10 may be provided as a wafer. Through-vias VI and through-insulating layers VL may be formed in the substrate 10. The through-vias VI may include first through-vias VI(1) and second through-vias VI(2). The through-vias VI may not penetrate a second surface 10b of the substrate 10. Interconnection lines 13, an interlayer insulating layer 11 covering the interconnection lines 13, first connection pads 15 disposed on the interlayer insulating layer 11 and a front passivation layer 17 covering the interlayer insulating layer 11 may be formed on a first surface 10a of the substrate 10. The substrate 10 may be bonded onto a carrier substrate by using a carrier adhesive layer in a state in which the first surface 10a of the substrate 10 faces the carrier substrate.

Referring to FIG. 3B, the second surface 10b of the substrate 10 may be back-ground to expose the through-insulating layers VL. At this time, the second surface 10b of the substrate 10 may be lower than a top surface of the through-insulating layer VL in the vertical direction.

Referring to FIGS. 3C and 3D, for example, chemical vapor deposition (CVD) processes or atomic layer deposition (ALD) processes may be performed to sequentially form first to third passivation layers 21, 23 and 25 covering the through-insulating layer VL exposed on the second surface 10b of the substrate 10. The first passivation layer 21 may fully cover the second surface 10b of the substrate 10 and the through-insulating layer VL. The second passivation layer 23 may cover a top surface of the first passivation layer 21. The third passivation layer 25 may cover a top surface of the second passivation layer 23. The first to third passivation layers 21, 23 and 25 may include different materials. For example, the first passivation layer 21 may include an oxide, the second passivation layer 23 may include a nitride, and the third passivation layer 25 may include an oxide. However, embodiments are not limited thereto, and, for example, the first to third passivation layers 21, 23 and 25 may include various inorganic materials.

Thereafter, a planarization process (e.g., a CMP process) or an etch-back process may be performed to remove portions of the through-vias VI, portions of the through-insulating layers VL, a portion of the first passivation layer 21, a portion of the second passivation layer 23, and the third passivation layer 25, and thus top surfaces of the through-vias VI may be exposed. For example, the planarization process (e.g., the CMP process) or the etch-back process may be performed to a fifth level LV5 of FIG. 3C. Thus, a back passivation layer 20 including the first and second passivation layers 21 and 23 may be formed. Top surfaces of the through-vias VI, the through-insulating layers VL, the first passivation layer 21 and the second passivation layer 23 may be coplanar with each other.

Referring to FIG. 3E, first mask patterns PR1 used to perform an etching process may be formed on the second passivation layer 23. The etching process may be performed to remove a portion of the first passivation layer 21, a portion of the second passivation layer 23 and a portion of the through-insulating layer VL, thereby forming a trench TC exposing a top surface and a side surface of the first through-via VI(1). The trench TC may be formed in portions of the first and second passivation layers 21 and 23 and may be formed to define a position and a planar shape of a first conductive pad CP1. For example, the etching process may be performed using a wet etching process or a dry etching process (e.g., a sputtering etching process or a reactive ion etching process).

Referring to FIG. 3F, the first mask patterns PR1 may be removed, and then, a physical vapor deposition (PVD) process may be performed to form a first barrier layer BR1. The first barrier layer BR1 may cover an inner surface of the trench TC and the second passivation layer 23.

Referring to FIGS. 3G and 3H, an electroplating process may be performed to form a conductive layer CM covering the first barrier layer BR1 and filling the trench TC.

Thereafter, a planarization process (e.g., a CMP process) or an etch-back process may be performed to remove portions of the through-vias VI, a portion of the through-insulating layer VL, a portion of the first passivation layer 21, a portion of the second passivation layer 23, a portion of the first barrier layer BR1, and a portion of the conductive layer CM. For example, the planarization process (e.g., the CMP process) or the etch-back process may be performed to a sixth level LV6 of FIG. 3G. Thus, a first pad portion PT1 and a first barrier pattern BT1 may be formed. Top surfaces of the through-vias VI, the through-insulating layer VL, the first passivation layer 21, the second passivation layer 23, the first barrier pattern BT1 and the first pad portion PT1 may be exposed.

Referring to FIG. 3I, a physical vapor deposition (PVD) process may be performed to form a second barrier layer BR2 on the second passivation layer 23.

Referring to FIG. 3J, second mask patterns PR2 used to perform an electroplating process may be formed on the second barrier layer BR2. The second mask patterns PR2 may include openings exposing the second barrier layer BR2 and overlapping with the first and second through-vias VI(1) and VI(2), respectively. The electroplating process may be performed to form a conductive layer in the openings of the second mask patterns PR2, and thus second and third pad portions PT2(1) and PT2(2) may be formed.

Referring to FIG. 3K, the second mask patterns PR2 may be removed, and an etching process may be performed to remove the second barrier layer BR2 exposed on the second passivation layer 23, thereby forming second and third barrier patterns BT2(1) and BT2(2). Thus, first conductive pads CP1 and second conductive pads CP2 may be formed.

Referring to FIG. 3L, a photoimageable dielectric (PID) material may be formed on the second passivation layer 23 and may be patterned to form a pad insulating layer 40 covering the second passivation layer 23 and the first and second conductive pads CP1 and CP2. At this time, openings exposing the first and second conductive pads CP1 and CP2 may be formed. Bump structures 30 of FIG. 1B may be formed in the openings, and the substrate 10 may be separated from the carrier adhesive layer. Thus, the semiconductor die 1000 of FIGS. 1B and 1C may be manufactured.

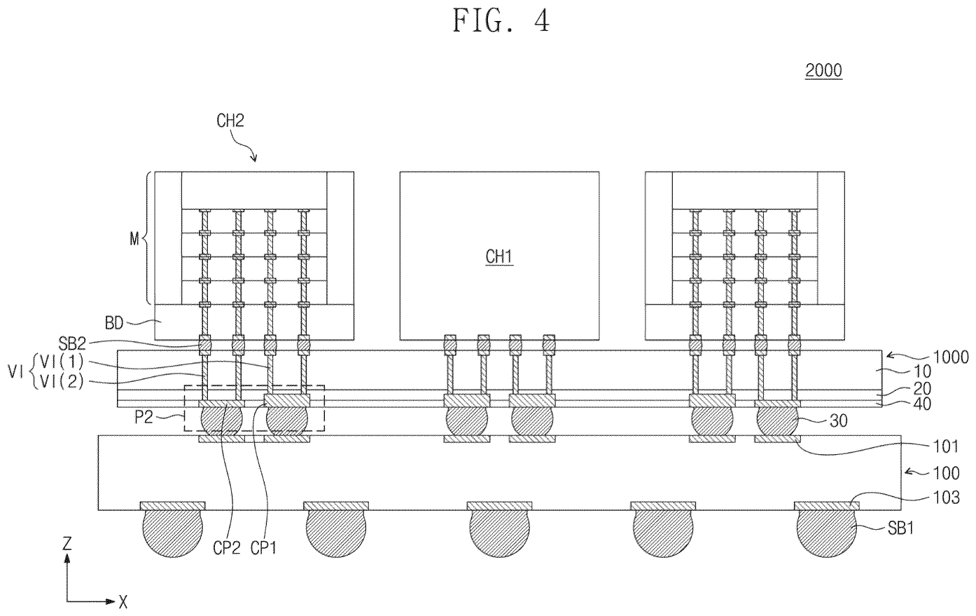

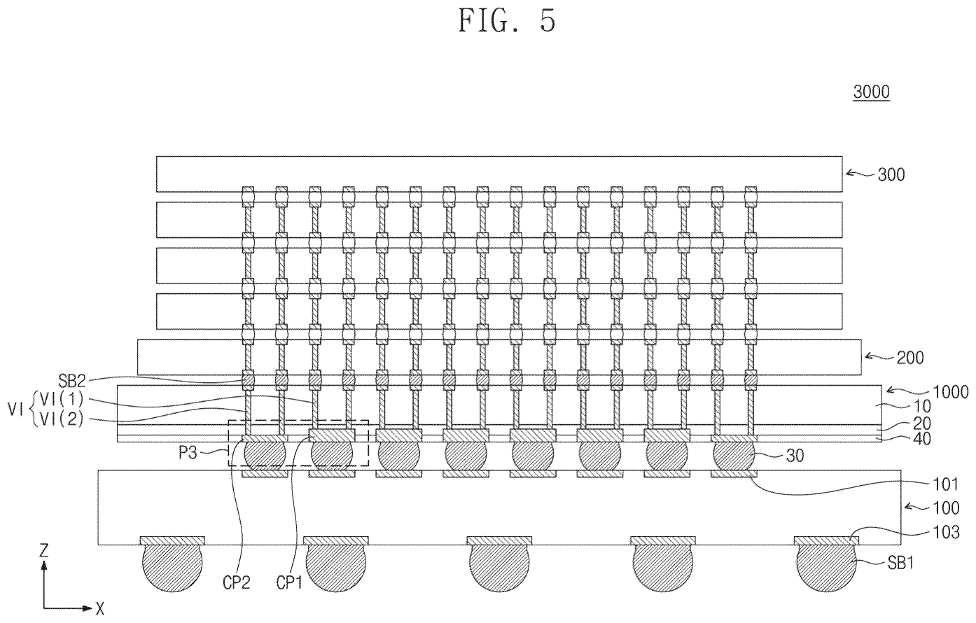

Next, semiconductor packages including at least one of the semiconductor dies of FIGS. 1A to 2 will be described with reference to FIGS. 4 and 5. The first surface 10a and the second surface 10b are located at a lower side and an upper side of the substrate 10, respectively, in FIGS. 1B to 3L, but the semiconductor die 1000 of FIGS. 1A to 2 may be turned over and mounted in each of semiconductor packages 2000 and 3000 of FIGS. 4 and 5. Thus, in each of the semiconductor packages 2000 and 3000 of FIGS. 4 and 5, the first surface 10a and the second surface 10b of the semiconductor die 1000 of FIGS. 1A to 2 may be referred to as a top surface and a bottom surface, respectively. For example, the portion ‘P1’ of each of FIGS. 1C and 2 may be an overturned view of each of portions ‘P2’ and ‘P3’ of the semiconductor packages 2000 and 3000 of FIGS. 4 and 5.

FIG. 4 is a cross-sectional view illustrating a semiconductor package according to one or more embodiments.

Referring to FIG. 4, the semiconductor package 2000 according to the one or more embodiments may include a package substrate 100, a semiconductor die 1000, and first and second semiconductor chips CH1 and CH2. The second semiconductor chip CH2 may be provided in plurality.

For example, the package substrate 100 may be a double-sided or multi-layered printed circuit board. The package substrate 100 may include second connection pads 101 provided at its top surface and third connection pads 103 provided at its bottom surface. First connection terminals SB1 may be bonded to and contact the third connection pads 103 of the package substrate 100.

The semiconductor die 1000 may be disposed on the package substrate 100. The semiconductor die 1000 may be the same/similar as the semiconductor die 1000 described with reference to FIGS. 1A to 2. The semiconductor die 1000 may be bonded to and contact the package substrate 100 through the bump structures 30. The semiconductor die 1000 may include interconnection lines connecting the package substrate 100 to the first and second semiconductor chips CH1 and CH2. An enlarged view of a portion ‘P2’ may be similar to an overturned view of one of FIGS. 1C and 2.

The first semiconductor chip CH1 and the second semiconductor chips CH2 may be disposed side by side in a first direction X on the semiconductor die 1000. Each of the first and second semiconductor chips CH1 and CH2 may be connected to the semiconductor die 1000 through second connection terminals SB2.

The first semiconductor chip CH1 may be an application specific integrated circuit (ASIC) chip or a system-on-chip. The first semiconductor chip CH1 may also be referred to as a host or an application processor (AP). For example, each of the second semiconductor chips CH2 may have a high bandwidth memory (HBM) chip structure. For example, each of the second semiconductor chips CH2 may include a base die BD and memory dies M sequentially stacked on the base die BD. According to another embodiment, the first semiconductor chip CH1 and the second semiconductor chips CH2 may be the same semiconductor chips. For example, each of the first and second connection terminals SB1 and SB2 may include at least one of a copper bump, a copper pillar, or a solder ball.

According to one or more embodiments, the first and second conductive pads CP1 and CP2 having different thicknesses may be disposed in different regions of the semiconductor die 1000. For example, similar to FIG. 4, the thicknesses of the first conductive pads CP1 disposed in a central portion of the semiconductor die 1000 may be greater than the thicknesses of the second conductive pads CP2 disposed in an edge portion of the semiconductor die 1000, and thus warpage of the semiconductor die 1000 may be reduced or prevented. Thus, it is possible to prevent non-wet failure or an electrical short which may occur between the package substrate 100 and the bump structures 30 when the semiconductor die 1000 is bonded to and contact the package substrate 100. As a result, the semiconductor package 2000 with improved durability and reliability may be provided.

FIG. 5 is a cross-sectional view illustrating a semiconductor package according to one or more embodiments.

Referring to FIG. 5, the semiconductor package 3000 according to the one or more embodiments may include a package substrate 100, a semiconductor die 1000, a first semiconductor die 200, and a second semiconductor die 300. The second semiconductor die 300 may be provided in plurality, and the plurality of second semiconductor dies 300 may be sequentially stacked.

For example, the package substrate 100 may be a double-sided or multi-layered printed circuit board. The package substrate 100 may include second connection pads 101 provided at its top surface and third connection pads 103 provided at its bottom surface. First connection terminals SB1 may be bonded to and contact the third connection pads 103 of the package substrate 100.

The semiconductor die 1000 may be disposed on the package substrate 100. The semiconductor die 1000 may be the same/similar as the semiconductor die 1000 described with reference to FIGS. 1A to 2. The semiconductor die 1000 may be bonded to and contact the package substrate 100 through the bump structures 30. The semiconductor die 1000 may include interconnection lines connecting the package substrate 100 to the first and second semiconductor dies 200 and 300. An enlarged view of a portion ‘P3’ may be similar to an overturned view of one of FIGS. 1C and 2.

The first semiconductor die 200 may be disposed on the semiconductor die 1000. The first semiconductor die 200 may be connected to the semiconductor die 1000 through second connection terminals SB2. For example, the first semiconductor die 200 may be a logic circuit chip. At least one or more second semiconductor dies 300 may be disposed on the first semiconductor die 200. For example, the second semiconductor dies 300 may be memory chips. According to another embodiment, the first and second semiconductor dies 200 and 300 may be the same semiconductor chips. For example, each of the first and second connection terminals SB1 and SB2 may include at least one of a copper bump, a copper pillar, or a solder ball.

According to one or more embodiments, the first and second conductive pads CP1 and CP2 having different thicknesses may be disposed in different regions of the semiconductor die 1000. For example, similar to FIG. 5, the thicknesses of the first conductive pads CP1 disposed in a central portion of the semiconductor die 1000 may be greater than the thicknesses of the second conductive pads CP2 disposed in an edge of the semiconductor die 1000, and thus warpage of the semiconductor die 1000 may be reduced or prevented. Thus, it is possible to prevent non-wet failure or an electrical short which may occur between the package substrate 100 and the bump structures 30 when the semiconductor die 1000 is bonded to and contact the package substrate 100. As a result, the semiconductor package 3000 with improved durability and reliability may be provided.

In the semiconductor die according to one or more embodiments, some of the pads disposed in a lower portion of the semiconductor die may have the structures partially buried in the passivation layer. The thicknesses of the pads disposed in the lower portion of the semiconductor die may be adjusted to compensate or offset an increase in density of the interconnection lines disposed on an upper portion of the semiconductor die, and thus expansion occurring at the upper portion and the lower portion of the semiconductor die may be controlled to minimize or prevent warpage of the semiconductor die. In addition, the thicknesses of the pads disposed in the central portion of the semiconductor die may be selectively increased to more effectively control the warpage. As a result, it is possible to prevent occurrence of non-wet failure or an electrical short between the bump structure of the semiconductor die and the package substrate when bonding the semiconductor die to the package substrate, and thus the semiconductor die with improved durability and reliability and the semiconductor package including the same may be provided.

While embodiments have been particularly shown and described, it will be understood by one of ordinary skill in the art that variations in form and detail may be made therein without departing from the spirit and scope of the attached claims and their equivalents.

What is claimed is:

1. A semiconductor die comprising:
a substrate comprising a first surface and a second surface which are opposite to each other;
interconnection lines on the first surface of the substrate;
an interlayer insulating layer on the first surface of the substrate and on the interconnection lines;
a back passivation layer on the second surface of the substrate;
through-vias penetrating the substrate;
a plurality of first conductive pads being in contact with some of the through-vias and on the second surface of the substrate; and
a plurality of second conductive pads being in contact with others of the through-vias and on the back passivation layer,
wherein each first conductive pad of the first conductive pads comprises:
a first pad portion buried in the back passivation layer;
a second pad portion protruding above the back passivation layer;
a first barrier pattern on a bottom surface and side surfaces of the first pad portion; and
a second barrier pattern between the first pad portion and the second pad portion.

2. The semiconductor die of claim 1, wherein the back passivation layer comprises:
a first passivation layer on the second surface of the substrate; and
a second passivation layer on a portion of the first passivation layer, a material of the second passivation layer being different from a material of the first passivation layer.

3. The semiconductor die of claim 2, wherein the first passivation layer comprises an oxide, and
wherein the second passivation layer comprises a nitride.

4. The semiconductor die of claim 2, wherein the first pad portion of each first conductive pad of the first conductive pads penetrates the second passivation layer and is buried in at least a portion of the first passivation layer,
wherein the second pad portion of each first conductive pad of the first conductive pads protrudes above the second passivation layer, and
wherein the second conductive pads are on a top surface of the second passivation layer.

5. The semiconductor die of claim 2, wherein each of the second conductive pads comprises:
a third barrier pattern and a third pad portion which are sequentially stacked, and
wherein the second barrier patterns and the third barrier patterns are on the top surface of the second passivation layer.

6. The semiconductor die of claim 2, wherein a level of a top surface of the first pad portion of each of the first conductive pads is equal to a first level of a top surface of the second passivation layer.

7. The semiconductor die of claim 2, wherein a second level of a bottom surface of each first conductive pad of the first conductive pads is between a third level of a top surface of the first passivation layer and a fourth level of a bottom surface of the first passivation layer.

8. The semiconductor die of claim 1, wherein the first pad portion of each first conductive pad of the first conductive pads is buried from a top surface of the back passivation layer by 1 μm to 5 μm in a vertical direction.

9. The semiconductor die of claim 1, wherein a width of each first conductive pad of the first conductive pads and a width of each second conductive pad of the second conductive pads ranges from 1 μm to 200 μm in a horizontal direction,
wherein a thickness of each first conductive pad of the first conductive pads ranges from 1 μm to 15 μm in a vertical direction, and
wherein a thickness of each second conductive pad of the second conductive pads ranges from 1 μm to 10 μm in the vertical direction.

10. The semiconductor die of claim 1, wherein a width of each through-via of the through-vias ranges from 1 μm to 30 μm in a horizontal direction, and
wherein a height of each through-via of the through-vias ranges from 1 μm to 120 μm in a vertical direction.

11. The semiconductor die of claim 1, further comprising:
a pad insulating layer on the first conductive pads, the second conductive pads, and the back passivation layer.

12. The semiconductor die of claim 1, wherein the first barrier pattern of each of the first conductive pads is between a corresponding one of the through-vias and the first pad portion of each first conductive pad of the first conductive pads.

13. A semiconductor die comprising:
a substrate comprising a first surface and a second surface which are opposite to each other;
interconnection lines on the first surface of the substrate;
an interlayer insulating layer on the first surface of the substrate and the interconnection lines;
a first passivation layer on the second surface of the substrate;
a second passivation layer on a portion of the first passivation layer, a material of the second passivation layer being different from a material of the first passivation layer;
through-vias penetrating the substrate;
a plurality of first conductive pads being in contact with some of the through-vias and on the second surface of the substrate;
a plurality of second conductive pads being in contact with others of the through-vias and on the second passivation layer;
bump structures connected to the first conductive pads and the second conductive pads, respectively; and
a pad insulating layer on the first conductive pads, the second conductive pads, and the second passivation layer,
wherein each first conductive pad of the first conductive pads comprises:
a first pad portion penetrating the second passivation layer and buried in the first passivation layer;
a second pad portion on the second passivation layer;
a first barrier pattern on a bottom surface and side surfaces of the first pad portion; and
a second barrier pattern between the first pad portion and the second pad portion,
wherein each of the second conductive pads comprises:
a third pad portion; and
a third barrier pattern on a bottom surface of the third pad portion,
wherein each first conductive pad of the first conductive pads has a first thickness, and
wherein each second conductive pad of the second conductive pads has a second thickness less than the first thickness.

14. The semiconductor die of claim 13, wherein a level of a top surface of the first pad portion of each first conductive pad of the first conductive pads is equal to a first level of a top surface of the second passivation layer,
wherein the first pad portion of each first conductive pad of the first conductive pads is buried from the first level by 1 μm to 5 μm a vertical direction, and
wherein a second level of a bottom surface of each first conductive pad of the first conductive pads is between a third level of a top surface of the first passivation layer and a fourth level of a bottom surface of the first passivation layer.

15. The semiconductor die of claim 13, wherein a width of each first conductive pad of the first conductive pads and a width of each second conductive pad of the second conductive pads ranges from 1 μm to 200 μm in a horizontal direction,
wherein the first thickness of each first conducive pad of the first conductive pads ranges from 1 μm to 15 μm in a vertical direction, and
wherein the second thickness of each second conductive pad of the second conductive pads ranges from 1 μm to 10 μm in the vertical direction.

16. The semiconductor die of claim 13, wherein the pad insulating layer comprises a photoimageable dielectric (PID) material.

17. The semiconductor die of claim 13, wherein the first barrier pattern of each of the first conductive pads is between a corresponding one of the through-vias and the first pad portion of each first conductive pad of the first conductive pads.

18. The semiconductor die of claim 13, wherein the first passivation layer comprises oxide, and
wherein the second passivation layer comprises nitride.

19. A semiconductor package comprising:
a package substrate;
a semiconductor die on the package substrate; and
a first semiconductor chip and a plurality of second semiconductor chips, which are side by side in a first direction on the semiconductor die,
wherein the semiconductor die comprises:
a die substrate;
a back passivation layer on a bottom surface of the die substrate;
through-vias penetrating the die substrate;
a plurality of first conductive pads being in contact with some of the through-vias and on the bottom surface of the die substrate;
a plurality of second conductive pads being in contact with others of the through-vias and on the back passivation layer; and
a pad insulating layer on the first conductive pads, the second conductive pads and the back passivation layer,
wherein the back passivation layer comprises:
a first passivation layer; and
a second passivation layer on the first passivation layer, a material of the second passivation layer being different from a material of the first passivation layer,
wherein each first conductive pad of the first conductive pads comprises:
a first pad portion penetrating the second passivation layer and buried in at least a portion of the first passivation layer;
a second pad portion protruding from the second passivation layer;
a first barrier pattern on a bottom surface and side surfaces of the first pad portion; and
a second barrier pattern between the first pad portion and the second pad portion,
wherein each of the second conductive pads comprises:
a third pad portion on a top surface of the second passivation layer; and
a third barrier pattern between the third pad portion and the second passivation layer.

20. The semiconductor package of claim 19, wherein the first pad portion of each first conductive pad of the first conductive pads is buried from a first level of an interface between the second passivation layer and the pad insulating layer by 1 μm to 5 μm in a second direction perpendicular to the first direction.
